(19) United States
(12) Patent Application Publication
(10) Pub. No.: US 2010/0055920 A1
(43) Pub. Date: Mar. 4, 2010

(54) Apparatus and method for enhancing plasma etch

(76) Inventor: Gang Grant Peng, Fremont, CA (US)

Correspondence Address: GANG GRANT PENG, 32 MISSION CIELO AVE, FREMONT, CA, 94539, US

(21) Appl. No.: 12/231,446

(22) Filed: Sep. 2, 2008

(51) Int. Cl. H01L 21/3065

(52) U.S. Cl. 438/710; 156/345.43; 257/E21.218

(57) ABSTRACT

The present invention discloses a new apparatus and method to enhance the plasma etch rate, etch selectivity and etch uniformity. The present invention will apply sonic waves to the work during plasma etch process. The sonic waves will enhance the plasma etch rate. The applied sonic waves can be of a mixture of multiple frequencies at the same time or at a different time. Applying different sonic frequency for etching different material will further amplify the etch selectivity. Sonic waves with multiple frequencies, especially with some lower frequency components, will further improve the etch uniformity over a large area.

### BACKGROUND OF THE INVENTION

(1) Field of the Invention

The present invention relates to the semiconductor process and particularly to the dry plasma etch process, which has been used broadly for making the integrated circuits (IC) on either silicon wafer or other materials.

(2) Prior Art

To make a semiconductor device on a semiconductor substrate (the work) requires many various processes, such as epitaxial film growth, film deposition, lithograph, etch, clean, implantation, chemical and mechanical polish. This invention will focus on the plasma etch process. The plasma etch techniques can be grouped into three, Chemical Reaction etching, Physical etching, and Reactive Ion Etching (RIE). In the chemical reaction etching, radicals in a plasma state are generated and react with a work. The reaction products are removed by vacuum. In the physical etching, ions are generated and accelerated to physically bombard a work. In the RIE, the etching action is generated by the radicals or neutrals and assisted by the ion bombardment. For the plasma etch, the etch products or product molecules are pumped away from the local reaction area, and then the fresh material underneath are exposed to the plasma and the incoming reactants for further etch reaction. As the size of the IC structure or the technology node becomes smaller and the aspect ratio becomes higher, removing the etch products from the local area, especially for the structure dense area, becomes crucial for the quality and efficiency of the etching process. There are two other new fields to making silicon based devices: one is the Micro Electrical Mechanical System (MEMS) and three dimensional-IC (3D-IC). Both of them need to remove a large amount of material comparing to the IC fabrication compared to the normal IC fabrication processes due to deeper and larger micro structures, hundreds of micrometer vs. nanometer respectively. For example, the 3D-IC may need to etch through the entire work.

Therefore, speeding up the plasma etch process will greatly improve the semiconductor manufactory's productivity and profitability.

It is well known that sonic energy can stimulate the chemical and electrochemical reactions because it promotes the reactants and the products transportation or diffusion process which moves the materials toward or away from the reaction region, as well as preventing certain reaction byproducts.

In the IC fabrication processes, the sonic energy—either ultrasonic or megasonic depending on their frequencies—have been broadly used for, mainly, wet processes. The most popular sonic applications are for the wet cleaning process, U.S. Pat. No. 6,681,782, the wet etch processes, U.S. Pat. Nos. 7,262,140 and 4,645,562, and the wet lift-off process which typically applies the ultrasonic wave to a chemical solution such as acetone, U.S. Pat. No. 6,821,451. There are a limited number of patents applying the sonic wave to the plasma etch processes.

U.S. Pat. No. 5,795,399 observed that when “a sonic wave is applied to the work after the processing operation, [Hence,] the reaction product attaching to the work during the processing operation is removed.” (column 2, lines 62-64). U.S. Pat. No. 5,795,399 observed that “when etching was performed while applying an ultrasonic wave to the wafer (the work), the etching rate was increased by about 1.5 times” (column 9, lines 9-11), The etching rate of tungsten silicide while applying an ultrasonic wave increased to 250 nm/min (column 10, lines 49-52) from 150nm/min (column 10, lines 42-45). U.S. Pat. No. 5,795,399 had two types of apparatus to apply the sonic energy, one has the sonic transducer inside its vacuum chuck (131 in FIG. 1. and FIG. 2a.), and another puts multiple sonic transducers on or inside etch chamber walls (FIG. 2b). U.S. Pat. No. 5,795,399 claimed to apply the sonic wave after the etching process either in a following chamber, “process the work in said second chamber” (column 18, line 61) and to “apply a sonic wave to the work in said third chamber” (column 18, lines 63-64), or after the etching process, “clean said semiconductor wafer (the work) by applying a sonic wave to said semiconductor wafer after plasma processing said semiconductor wafer (the work)” (column 20, lines 5-7). The separation between the plasma etch process and applying sonic wave will not have direct effect on the plasma etch process, except clean up the etch residual as claimed by U.S. Pat. No. 5,795,399 (claim 20).

U.S. Pat. No. 5,795,399 used the sonic wave of a KHz to a MHz (claims 3, 9, and 15), which is an ultrasonic wave (claims 4, 10, and 16). For a given power level, the ultrasonic wave will have longer wave length and larger max displacement (amplitude) compared to a higher frequency (megasonic wave) based on

$$Max displacement {u}_{m} = \frac{P}{k {ρ}_{0} {v}^{2}}$$

where v is the frequency of the sonic wave inside the work, P is the power, ρ₀ is the density and κ is a dimensionless constant. The larger max displacement may cause damage to the micro structures (121) on the work (111 in FIG. 3. and FIG. 4.) and also makes the work bounce on the chuck surface so that there has to be some additional mechanism to hold the work down to the chuck—a clamp was used in U.S. Pat. No. 5,795,399 (column 5, line 40). The extra mechanism will increase the complexity of the chuck, reduce the reliability of the chuck, and cause contamination. It used a clamp to hold down the work to the chuck.

U.S. Pat. No. 5,795,399 claimed to apply the sonic wave separated from the plasma etch process. The sonic wave can be applied either in the etch chamber, post etch process or in the following non-etch chamber, “processing the work in said second chamber, for processing the work in said second chamber; a sonic wave applying section, provided to said third chamber, for applying a sonic wave to the work in said third chamber” (claim 1, column 18, lines 59-63). It does “process the work; and apply a sonic wave to the work after [etch] processing the work” (claim 8, column 19, lines 28-30). The same process sequence of etching the work first and then applying the sonic wave to the work can be found in the rest of the claims of the U.S. Pat. No. 5,795,399 (claim 14, column 20, lines 5-7; clam 18, column 20, lines 28-33).

U.S. Pat. No. 6,017,396 claimed to put an ultrasonic chamber in between the two sputter deposition chambers to clean up the film surface (column 13, lines 47-52 and column 14 lines 48-52) in between two sputtering steps. Also the ultrasonic wave doesn't directly interact with the plasma sputtering process.

Similar as the claims in U.S. Pat. No. 5,795,399, U.S. Pat. No. 6,766,813 also invented the installation of a sonic wave transducer inside its vacuum chuck to deliver the sonic wave from the back side of the wafer for a wet clean process.

As described above, a means to provide a better way to directly stimulate the plasma etching process is needed for promoting the etch productivity and material selectivity.

### SUMMARY OF THE INVENTION

The present invention provides a means of improving semiconductor device manufactory productivity and material selectivity. The primary object of the present invention is to improve the etching efficiency for the plasma etching process for semiconductor device manufactory while maintaining all the plasma process conditions unchanged from normal process conditions which don't use sonic wave. The second object of the present invention is to improve the etching selectivity for the plasma etching process for semiconductor device manufactory while maintaining all the plasma process conditions unchanged from normal process conditions which don't use sonic wave. The third object of the present invention is to improve the uniformity of the plasma etching process for semiconductor device manufactory while maintaining all the plasma process conditions unchanged from normal process conditions which don't use sonic wave. Overall, the present invention will make the semiconductor device manufactory more cost effective.

To achieve the first object, the present invention will couple the sonic energy with the plasma etch process by applying the sonic wave to the work during the plasma etching process, which increases the material removal rate of the etching process.

To achieve the second object, the present invention will apply different sonic waves to the structure or film according to its material properties during the plasma etch process, e.g. with different material film, the sonic wave may be applied differently, such as different frequency and power, to enhance the difference between the etch rate of these films. The frequency of the sonic wave and the total power of the sonic energy may be predetermined and varied accordingly.

To achieve the third object, the present invention will apply multiple frequencies, high and low frequencies, to the work during the plasma etch process. The sonic wave with relatively lower frequencies produces the longer wave length and will improve the etching uniformity over a large area.

The present invention has the following advantages.
1. It provides a new process control to change the material etch rate only while keeping the other plasma etch process conditions, such as the bombardment and or the reactant concentration the same. This new process control will be independent from other plasma process parameters such as bias, gas flow rate, plasma power, and total chamber pressure.
2. It is comparable with any reactants because the sonic transducer is not directly exposed to the plasma.
3. It responds instantly unlike the other properties such as the pressure and temperature, which are very important for precisely in-situ control of the plasma etch process.
4. It does not use any additional consumables other than the ones for the plasma etch process. Therefore, the plasma etch process with sonic wave(s) remains the same plasma chemistry and complexity as for a normal non-sonic wave plasma etch process, but the etch productivity improves significantly.

Further objects and advantages of the present invention will become apparent from a consideration of the ensuing description and drawings.

### BRIEF DESCRIPTION OF THE SEVERAL VIEWS OF DRAWINGS

The novel features believed characteristic of the present invention are set forth in the claims. The invention itself, as well as other features and advantages thereof will be best understood by referring to detailed descriptions that follow, when read in conjunction with the accompanying drawings.

FIG. 1. shows a diagram of the apparatus for plasma etch process according to prior art.

FIG. 2a. shows a diagram of the apparatus for plasma etch process with an ultrasonic transducer inside its chuck according to prior art.

FIG. 2b. shows a diagram of the apparatus for plasma etch process with sonic transducers on or inside the chamber walls according to prior art.

FIG. 3. shows a diagram of the apparatus for plasma etch process with sonic transducers inside its chuck according to the present invention.

FIG. 4. is a cross sectional view of the work with patterns on according to the present invention.

FIG. 5a and 5b. are schematic models of the specimen motion during plasma etch using sonic wave according to the present invention.

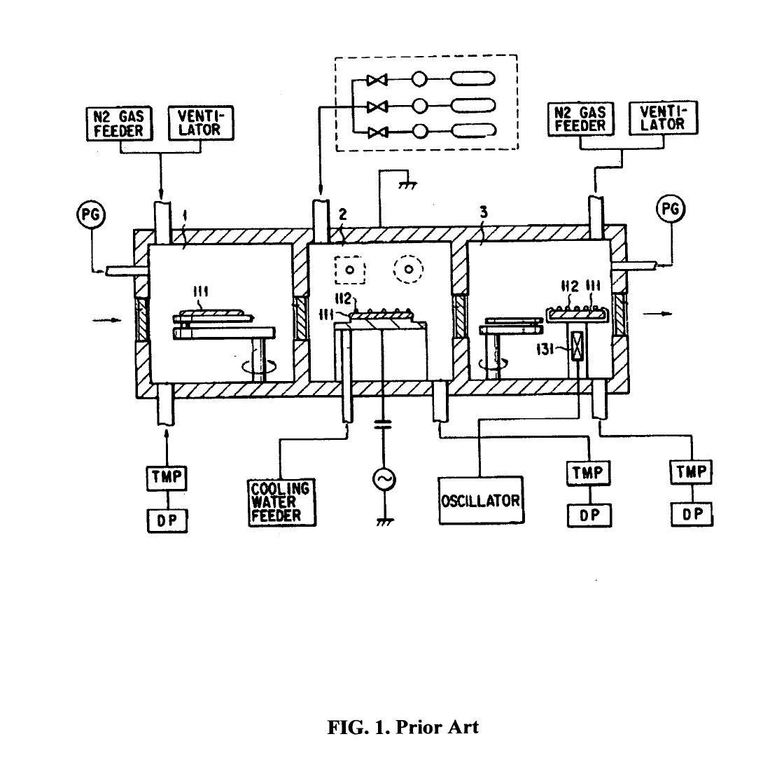

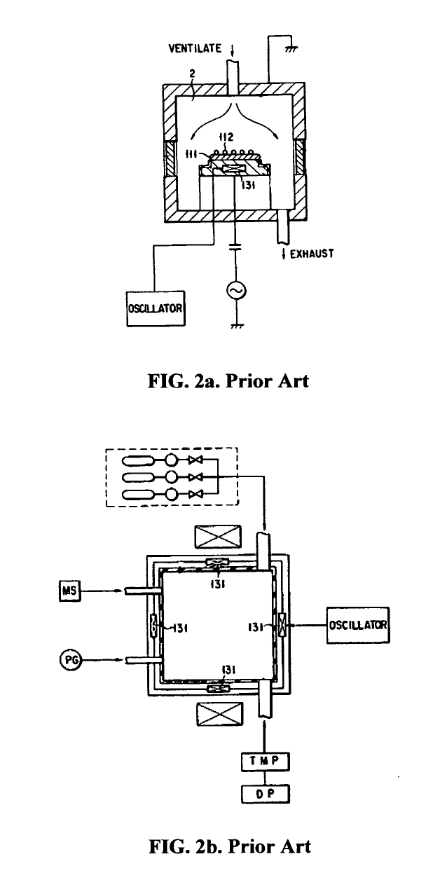

### DETAILED DESCRIPTION OF THE INVENTION

While embodiments of the present invention will be described below, those skilled in the art will recognize that other assemblies, configurations, and processes are capable of implementing the principles of the present invention. Thus the following description is illustrative only and not limiting.

Reference is specifically made to the drawings wherein like numbers are used to designate like members throughout.

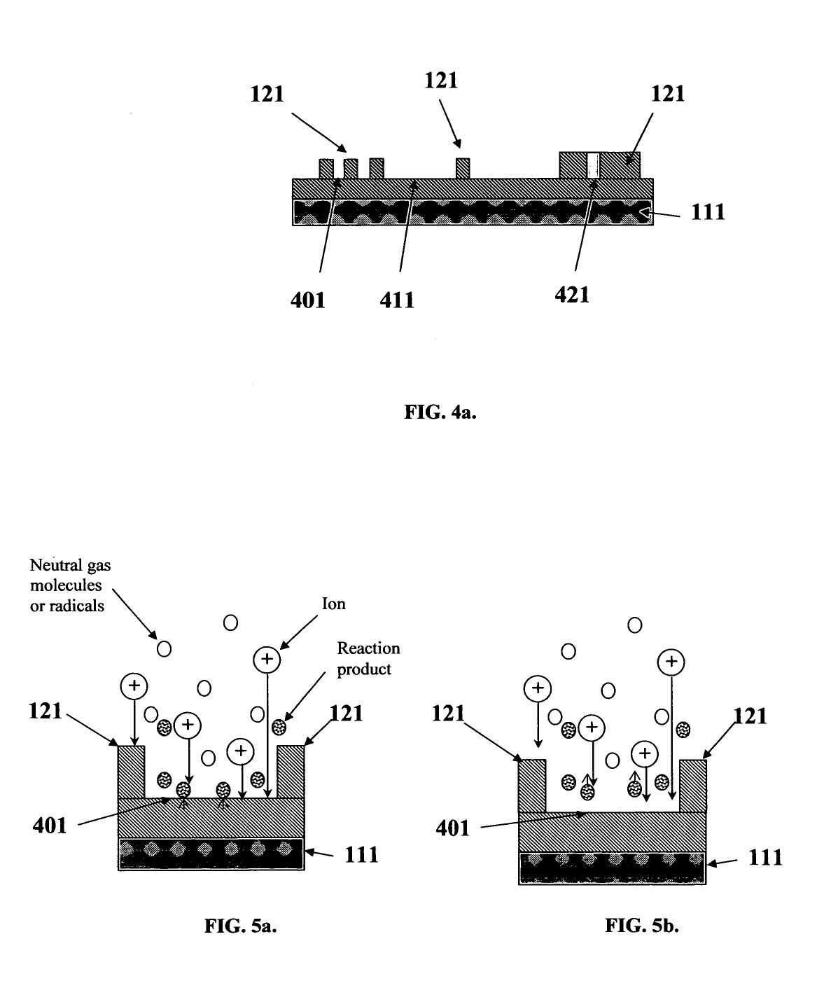

Note the followings:
(1) The dimensions of all of drawings are not to scale.
(2) A pattern wafer (the work) as embodiments of the present invention are illustrated in FIG. 4. However the same or similar etch process is applicable to other micro structures of semiconductor chips or devices.
(3) The work of a semiconductor chip may be silicon, silicon oxide, GaAs, or other materials.
(4) There are either at least one or multiple sonic transducers and/or multiple sonic sources contacted against the same chuck for all configurations of the etch chamber in the present invention.
(5) The multiple sonic transducers may be the same type or shape or different types or shapes or combination of types and shapes and combination of different sequences to apply sonic waves according to the present invention.
(6) The sonic transducers may have single or multiple frequencies for each of them during the plasma etch process in the present invention.
(7) The sonic transducers may have the same or different power and operation setting duration time during the plasma etch process in the present invention.
(8) The sonic transducers may have on and off operations the same time or different times during the plasma etch process in the present invention.
(9) The sonic waves may be applied at different sequences, e.g. at the same time or different times applied to the same or different frequencies at the same or different transducers.

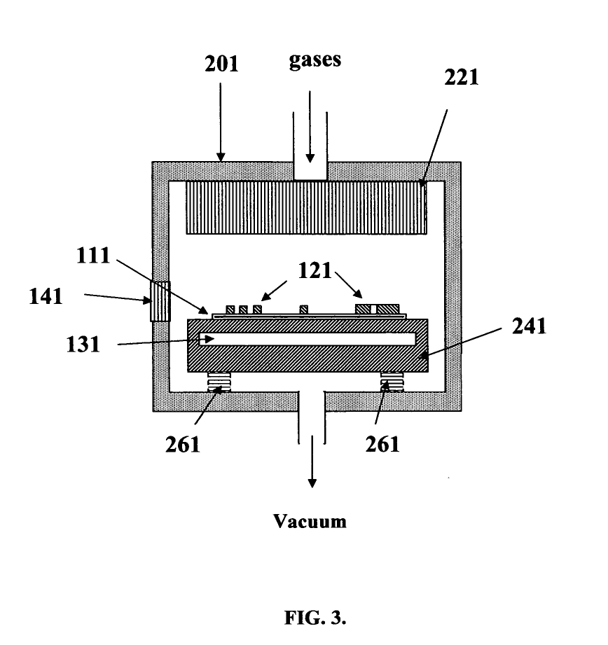

FIG. 3. shows a diagram of the apparatus for the plasma etch process with a sonic transducer 131 inside the chuck 241 according to the first, the second, and the third embodiments of the present invention. The sonic transducer 131 can be a single transducer or a combination of multiple transducers. The plasma etch chamber 201 has an up electrode 221 and a low electrode. The reaction gases are delivered to the chamber through the up electrode 221. The lower electrode is combined with the chuck 241.

According the first embodiment of the present invention, the work 111 is loaded through the load-lock door 141 to the chuck 241 either under the condition of vacuum or atmosphere. The sonic transducer 131 is turned on before the plasma starts. Then the plasma etch process starts and after the plasma etch process finished the sonic wave will be turned off. Then the work 131 is unloaded from the chamber 201.

The power and frequency of the sonic wave can be predetermined for each individual film or for the entire film stack based on either experiences or theoretical prediction. During the plasma etch process, the power and the frequency of the sonic wave may be changed in order to reach the optimal performance to meet the process requirements according to the second embodiment of the present invention. The changes of the sonic power and frequency may be trigged by the signal from an end point detection apparatus.

There may be multiple sonic waves applied through the sonic transducer 131 to the work during the plasma etch process. The sonic transducer may be a set of transducers or multiple individual transducers. The power and frequencies of the sonic waves can be very different according to the embodiment of the present invention. Normally, a set of tests of the combination of the transducers' powers and frequencies need to be run to determine the best process parameters for each particular plasma etch process. The criteria for the set of tests will be the etch rate, etch selection, and etch uniformity.

FIG. 4. is a cross sectional view of a work. The plasma etch process normally happens at the bottom of structures, where the fresh material is exposed to the plasma, e.g. the bottom of lines, a trench 411, the open area 421, and the bottom of a via 431.

FIG. 5a and FIG. 5b. are the schematic models of the specimen during the plasma etch process. The plasma etch process involves neutral gas molecules (radicals etc.), active ions and product molecules. While the sonic wave is applied to the work 111, the work 111 vibrates and the open areas 411, 421, and 431 move along, up and down. When the work 111 moves up, the reaction products in the open areas 411, 421, and 431, which feel the impact and therefore lose-up. When the work 111 moves down, the reaction products separate from the open areas 411, 421, and 431.

During the plasma etch process, the gas molecules come down from the up electrode 221 in FIG. 3. The reactive ions or radicals react with the atoms on the specimen surface 421 to form gaseous reaction products at the open areas 411, 421, and 431. The reaction products, likely being volatile, will be moved away from the surface by constant pumping of the process chamber and then other ions or radicals can reach the surface for further reaction. The reaction products are moved away from the open areas 411, 421, and 431. This is a diffusion controlled process which is slow when the system pressure is low and the open area is small. Increasing the physical impact of energized ions will increase the reaction rate (the etch rate) to a certain degree due to the limits of the hardware, e.g. the RIE process. But for plasma etching processes more chemical etching like, the overall ion impact is weak. The present invention uses a sonic wave(s) to provide additional energy to the surface by high frequency vibration(s) of the work 111. The surface vibration of the work will have impact on the reaction product molecules and initialize their vertical motion (away from the open areas 411, 421, and 431). When the reaction product molecules moves far enough from the surface, they will be pumped away by the system's vacuum.

In the present invention, the sonic wave frequency may have the range of a MHz to a GHz. The selection of a particular frequency to be used for a plasma etch process depends on many factors such as the size and geometry of the etched structure, the material of the current etching film, the materials adjacent to the current etching film, and the overall needs of the vibration displacement on the work surface.

The second embodiment of the present invention, the material selectivity of the plasma etch process, can be achieved by applying different frequencies and sonic power at the boundary of film currently etching. For example, a plasma etch process is for etching a silicon oxide film over a poly silicon film. The sonic wave has been selected at a lower frequency to match the silicon oxide film's acoustic property to increase its silicon oxide etch rate. When the etch process just passes to the boundary of the silicon oxide film and the poly silicon film becomes the etching film, the unmatched sonic wave has weak effect on the poly silicon etch rate. Therefore, the difference of the etch rates between these two films enlarged. Then, the sonic wave switched to a higher frequency to match the poly silicon's film's acoustic property and the high etch rate of the poly silicon obtained. The selection rule of the frequency and power of the sonic wave is to maximize the difference between material etch rates (material etch selectivity) as well as to maximize the etch rate for each material separately.

The third embodiment of the present invention, the etch rate uniformity over the work can be achieved by applying additional sonic waves with lower to higher frequencies. The low frequency sonic wave can be a MHz wave or an even lower frequency. It moves the work slower with a larger displacement over a large area, which matches the motion of the heavier neutral molecules and radials. Meanwhile, the higher frequency still independently stimulates the reaction products' vertical motion.

An example to illustrate the operation procedure of the present invention will be a silicon etch process for a very deep structure about hundreds of micrometers. A normal silicon plasma etch process will take a long time (tens of minutes) for etching such deep structures, and a strong bias for high ion bombardment has to be used to increase the silicon etch rate. Also the process may have to take a tool break during the etch process due to the heat generated by the high power silicon etch. The present invention will operate as the following. The silicon plasma etch process can be started with the usual process conditions such as the chamber pressure, gas flow rate and the ratio between different gases, the chuck and the work temperature, the electrode temperatures, plasma power, and bias power. After a couple of micrometers of silicon is removed, the sonic wave with the frequency matching the silicon acoustic property can be introduced to the etch process. The entire silicon etch process will take much less time to finish due to the high etch rate and no need for a tool break.

The present invention has been discussed by the way of the first, second and third embodiments. These embodiments can be used as a combination of all of three or just one or two and the combinations may have different operational sequences.

Although the description above contains many specifications, these should not be construed as limiting the scope of the present invention but as merely providing illustrations of some of the presently preferred embodiments of the present invention.

Therefore the scope of the present invention should be determined by the claims and their legal equivalents, rather than by the examples given.

### REFERENCES CITED

US PAT. DOCUMENTS

| | | | |
|---|---|---|---|
| 7,260,240 | Aug. 21, 2007 | Tran et al. | 382/101 |
| 6,681,782 | Jan. 27, 2004 | Bran et al. | 134/148 |
| 6,766,813 | Jul. 27, 2004 | Sayka et al. | 134/148 |
| 6,017,396 | Jan. 25, 2000 | Okamoto et al. | 118/719 |
| 5,795,399 | Aug. 18, 1998 | Hasegawa et al. | 134/1.3 |
| 4,645,562 | Feb. 24, 1987 | Liao et al. | 156/643 |

1. An apparatus for semiconductor device manufactory, comprising:
a chamber for processing the work having a port for loading and unloading a work;
a chuck in said chamber to support said work;
a sonic wave transducer assembly contacting said chuck, for providing sonic wave to said work on said chuck in said chamber;
an up electrode in said chamber for delivering plasma and gases;
a lower electrode in said chamber for supporting said process.

2. An apparatus according to claim 1, wherein said sonic wave transducer section includes:
a supporter of the work;
a sonic wave applying device connected to said support for applying the sonic wave to the work through said supporter.

3. An apparatus according to claim 1, wherein the sonic wave transducer assembly is a single transducer.

4. An apparatus according to claim 1, wherein the sonic wave transducer assembly is a combination of multiple transducers.

5. An apparatus according to claim 1, wherein the sonic wave transducer assembly is of multiple individual transducers.

6. An apparatus according to claim 3, wherein the sonic wave transducer assembly has a frequency in the range of a MHz order to a GHz order.

7. An apparatus according to claim 3, wherein the sonic wave transducer assembly has a sonic sweeping across each transducer.

8. An apparatus according to claim 4, wherein each transducer in said sonic wave transducer assembly may have a frequency different from other said transducers in said assembly.

9. An apparatus according to claim 2, wherein said sonic wave applying device includes:
a sonic generator;
a sonic wave sweep controller; and
a matching network for power amplification.

10. An apparatus according to claim 2, wherein said sonic wave applying device included:
sonic generators and each said sonic generators is for one or several sonic wave transducers in said sonic wave assembly;
a sonic wave sweep controller for each sonic wave transducers in said sonic wave assembly;
matching networks for each said power amplifications.

11. An apparatus according to claim 10, wherein each matching network of said matching networks is for one or more sonic transducers in said sonic wave assembly.

12. An apparatus according to claim 1, wherein each sonic wave transducer assembly may have a frequency different from other sonic wave transducer in said assembly in the range of a KHz order to a GHz order.

13. A method of enhancing plasma etch process productivity, comprising of the following steps:
loading a work into the plasma etch process chamber;
applying the sonic wave to said work prior to said etch process;
applying said sonic wave to the work through the plasma said etch process, thereby increasing the material etch rate;
applying said sonic wave with timing control to sweep across each transducer from said sonic wave transducer assembly to said work through said etch process;
applying the sonic wave with different frequencies to said work when said etch process advanced into different film on said work, thereby improving material selectivity;
turning off said sonic wave after said etch process finished;
unloading said work from said plasma etch process chamber.

14. A method according to claim 13, wherein the sonic wave has a frequency range from a KHz order to a GHz order.

15. A method according to claim 13, wherein said sonic wave sequentially excites each sonic wave transducer in said sonic wave transducer assembly for a short time of a microsecond order to a millisecond order.

16. A method according to claim 13, wherein the sonic wave has multiple frequencies range from a KHz order to a GHz order.

17. A method according to claim 13, wherein the one or several frequencies of said applying sonic wave to said work can be turned on or off while the other frequencies of said applying sonic wave stay on.

18. A method according to claim 13, wherein the sonic powers for one or several waves of said applying sonic wave to said work can be different from the others.
